(19) United States
(12) Patent Application Publication
(10) Pub. No.: US 2024/0038629 A1
(43) Pub. Date: Feb. 1, 2024

(54) MULTILAYER THERMAL INTERFACE MATERIAL FOR INTEGRATED CIRCUITS

(71) Applicant: GM Cruise Holdings LLC, San Francisco, CA (US)

(72) Inventor: Yafei Han, Sunnyvale, CA (US)

(73) Assignee: GM Cruise Holdings LLC, San Francisco, CA (US)

(21) Appl. No.: 17/815,176

(22) Filed: Jul. 26, 2022

(51) Int. Cl. H01L 23/427; H01L 23/552; H01L 21/48; H05K 1/02; H01L 23/473

(52) U.S. Cl. CPC H01L 23/427; H01L 23/552; H01L 21/4882; H05K 1/0209; H01L 23/473; H05K 2201/064; H05K 2201/066

(57) ABSTRACT

There is disclosed by way of example a computing apparatus, having a packaged circuit with an exterior surface, a heat sink having a pedestal disposed to nearly contact the packaged circuit with a nominal clearance when the packaged circuit is assembled to the heat sink, and a first thermal interface material (TIM) and a second TIM disposed in layers between the packaged circuit and the pedestal, wherein the first TIM is non-flowable at operating temperatures of the packaged circuit, and the second TIM is flowable at the operating temperatures.

### BACKGROUND

### 1. Technical Field

The present disclosure generally relates to electronic circuits and, more specifically, though not exclusively, to a multilayer thermal interface material (TIM) for integrated circuits.

### 2. Background

Modern computing architectures use very small feature sizes, such as nanometer scale features in integrated circuits.

### BRIEF DESCRIPTION OF THE DRAWINGS

The various advantages and features of the present technology will become apparent by reference to specific implementations illustrated in the appended drawings. A person of ordinary skill in the art will understand that these drawings show only some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates an example system environment that may be used to facilitate autonomous vehicle (AV) dispatch and operations, according to some aspects of the disclosed technology.

FIG. 2 illustrates a block diagram of selected components of an AV controller module, according to some aspects of the disclosed technology.

FIGS. 3A and 3B illustrate selected components of an AV controller module, including cooling components, according to some aspects of the disclosed technology.

FIG. 4 illustrates selected components of a cooling configuration, according to some aspects of the disclosed technology.

FIG. 5 illustrates selected components of a cooling configuration, according to some aspects of the disclosed technology.

FIG. 6A illustrates selected components of a cooling configuration, according to some aspects of the disclosed technology.

FIG. 6B illustrates selected components of a cooling configuration, according to some aspects of the disclosed technology

FIG. 7A illustrates selected components of a cooling configuration, according to some aspects of the disclosed technology.

FIG. 7B illustrates selected components of a cooling configuration, according to some aspects of the disclosed technology.

FIG. 8 illustrates selected components of a cooling configuration, according to some aspects of the disclosed technology.

FIG. 9 illustrates an example processor-based system with which some aspects of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring the concepts of the subject technology.

Very large-scale integration (VLSI) of microscopic transistors may realize very high operating speeds, such as at a gigahertz scale, and high transistor density. This provides highly capable integrated circuits (IC) that can perform difficult tasks, such as operating an AV. An AV controller is used in this specification as an embodiment that illustrates the teachings of the present specification. This illustration should be understood to be nonlimiting. The teachings of this specification may be applicable to many other contexts in which ICs operate, such as in single-board computers, personal computers (PCs), laptops, cell phones, embedded controllers, and others.

Dense transistors with small feature sizes and correspondingly low impedance operating at very high frequencies may inherently draw high current. In turn, this drives relatively higher I²R heat loads on the ICs. Thus, in many modern electronics, heat dissipation and heat management may be important performance considerations.

One method of providing heat dissipation is to use a TIM to draw heat away from the surface of an IC package and conduct the heat to some kind of heatsink that can then dissipate the heat effectively. Two popular species of TIM may include a thermal pad and a flowable material such as a thermal paste.

As used in this specification, a thermal pad may include a rigid, semirigid, or flexible padding that may be applied to the surface of an IC. Embodiments of a thermal pad may include a pad with a foam rubber-like consistency, which is not pourable but that is deformable. Illustrative thicknesses for such a thermal pad may include pads of a thickness between 0.5 millimeters and 1.5 millimeters or, more specifically, 0.5, 0.55, 0.6, 0.65, 0.7, 0.75, 0.8, 0.85, 0.9, 0.95, 1.0, 1.05, 1.1, 1.15, 1.2, 1.25, 1.3, 1.35, 1.4, 1.45, or 1.5 millimeters by way of illustrative and nonlimiting example. The nominal thickness of different thermal pad options may have a larger range, for example, from 0.5 mm to 3.0 mm, and in some cases up to 5.0 mm. Off-the-shelf thicknesses are often with a 0.25 mm resolution interval (e.g., any thickness in the range 0.5 mm, 0.75 mm, 1.0 mm, 1.25 mm 4.75 mm, 5.0 mm). In some cases, special thicknesses between the interval may also be custom-made.

An alternative to a thermal pad is a pourable or flowable material, such as a thermal paste. A thermal paste may be, by way of illustration, a relatively viscous material that holds its shape well but is pourable or dispensable. For example, thermal paste may be dispensed from a tube, fluid guide, nozzle, or other means. Thermal paste may have a consistency similar to putty or other pastes and paste-like materials.

In common practice, a system designer may generally elect to use thermal paste or thermal pads in a particular design. In some cases, a mixture of thermal paste and thermal pads may be used, such as by applying thermal paste to some components and thermal pads to other components. Thermal paste and thermal pads may have different advantages and disadvantages as compared to one another.

For example, thermal paste is much more pliable than a thermal pad and may not have a fixed shape or volume. Rather, it can be applied directly to a surface. One advantage is that the thermal paste has a liquid-like property of conforming very closely to the surface on which it is placed. Thus, minor manufacturing imperfections in the surface of the heatsink and/or the IC package can be filled by the thermal paste. This may provide good surface contact across the entire surface of the thermal paste and provide a more complete thermal interface between the IC package and the heatsink. On the other hand, thermal paste may generally be thinner than a thermal pad and may thus require the heatsink to more nearly contact the ICs.

In a design example, a so-called cold plate may be used as a heatsink. The cold plate may be manufactured specifically to interface with a specific printed circuit board (PCB) with a number of known ICs. The cold plate may be made of metal, such as aluminum or copper, which is highly conductive. It may be cooled in various ways, such as by evaporative cooling or by supplying cooled liquid, such as water, Freon, or other liquid to the cold plate and providing a return exhaust path where the cooling liquid can carry away heat. The heated liquid can then be cooled by the ambient environment or actively cooled, such as with an evaporator.

Such a cold plate may have a form factor that specifically interfaces with the known PCB. This may include several “pedestals,” which are protrusions from the cold plate that are designed specifically to mate proximate to high heat zones of the PCB, such as various ICs. However, it may not be practical to design the cold plate such that the pedestals physically contact the ICs. It may be desirable instead to provide a more flexible TIM between the pedestal and the IC. The TIM can conduct heat away from the IC and up to the pedestal of the cold plate and, because it is not completely rigid like the cold plate, there is less danger of damaging the IC.

One advantage of a thermal paste interface between the IC and the cold plate is the cold plate may be manufactured with looser tolerances. This is because the dispensing volume of the thermal paste can be controlled so that it may be guaranteed to fill the entire gap between heatsink and IC (by increasing the volume), while with the benefit of being more pliable and easier to deform, it creates a lower peak pressure on the IC during and after the assembly process, even if excessive volume has been dispensed before assembling the PCB with the cold plate. In contrast, the thermal pad comes with a pre-set thickness, so the gap size and tolerance may need to be more closely controlled to guarantee both good interface contact and in-range compression pressure on the IC during and after assembly. A larger gap may lead to bad or no direct interface contact, while a smaller gap may lead to over-compression of the IC.

However, thermal paste may also have disadvantages, for example, the assembly process may be more complex, and the dispensing operation may require special equipment. The thermal paste may also lack electromagnetic interference (EMI) shielding capability.

Thus, some embodiments opt for a thermal pad with a rubber or foam rubber-like consistency as an interface between the IC and the pedestal. The thermal pad may have a relatively higher heat conductivity as compared to the thermal paste. It may also be manufactured with a fixed shape and size and may thus be mated closely to the design of the IC and the cold plate.

In some cases, a disadvantage may include that the thermal pad is not flowable like the thermal paste and thus may conform less precisely to the respective surfaces of the IC and the pedestal. This may result in imperfect conduction between the two and, in some cases, may result in small hotspots on the IC package where there is insufficient contact between the thermal pad and the IC. Another disadvantage of the thermal pad may include expansion. As the assembly heats up, both the IC and the cold plate/heatsink may expand, thus compressing the thermal pad between them. In at least some thermal pad designs, the thermal pad is compressible but may not be highly “reboundable.” In other words, once the pad is compressed, it stays compressed either permanently or for a long enough time to be an issue. Because the pad is compressed as the system heats, when the system later cools, small gaps may form between the thermal pad and the pedestal. This may inhibit thermal conduction.

One advantage of thermal pads is that they can be manufactured with electromagnetic interference (EMI) shielding or dissipating properties. For example, a thermal pad may have a metallic mesh or foil, which absorbs electromagnetic radiation. It may also be infused with materials that absorb electromagnetic radiation. Again, turning to an AV as an illustrative example, EMI may be an important operational design consideration. Electromagnetic noise coming from the various ICs on the AV controller may interfere with various wireless systems, such as wireless sensors, wireless communication, and others. Thus, it may be desirable in some designs to enhance EMI shielding and absorption. Thermal pads advantageously can be provided with EMI absorption materials. These thermal pads may help the PCB that hosts the AV controller to conform to EMI limits and requirements.

In an experimental test case, certain species of thermal pads were found to provide much better electromagnetic isolation for ICs than thermal paste. However, thermal paste was found to provide slightly better heat conduction, especially during a reliability test, even though the thermal paste had a lower nominal heat conductivity.

Another design consideration is that the ICs may have some fragility, such as fragile solder points and/or fragile packaging. Thus, although the thermal pads could be designed to provide sufficient heat conductivity and good EMI isolation, design tolerances for these properties may be such that pressure on the pads could pose a danger of damaging the ICs, and in particular the solder joints.

Advantageously, embodiments disclosed herein may provide a multilayered TIM in which both a thermal pad and a thermal paste are used together in a layered configuration. In an illustrative example, a thermal pad may provide heat conduction and EMI shielding. A cold plate may be manufactured with pedestals that have sufficient clearance from the ICs that they do not directly contact or compress the thermal pad. Instead, a layer of thermal paste may be used as a direct interface between the thermal pad and the cold plate. Advantageously, the compression pressure on the ICs may be greatly reduced because of the added layer of thermal paste, which may pose less danger for damaging the IC or its solder joints. Further advantageously, this configuration has been found to have similar and, in some cases. nearly identical heat dissipation properties as compared to using thermal paste alone or thermal pads alone. Further advantageously, the use of a thermal paste may provide the very close conformity to a surface that can provide more uniform heat dissipation, while the combination with the thermal pad can provide enhanced EMI properties. This configuration may also provide increased reliability after experiencing assembly thermal expansion, since the thermal paste has a better bonding capability at the interfaces and also has a better “rebounding” ability when temperature drops and the gap increases

The multilayered TIM of the present specification can be provided in a number of configurations. In an example, a layer of thermal paste is applied directly to the IC, while the thermal pad may be adhered to a pedestal of the cold plate. One advantage of this configuration is that the cold plate may be made of a machined metal, which in some cases may be machined to very tight tolerances so that the surface is extremely smooth. Thus, the thermal pad may provide very good adhesion to and contact with the cold plate pedestal. The IC package may have more surface irregularities, and thus a layer of thermal paste may be applied to the IC package.

In the same or a different embodiment, the thermal pad may be applied directly to the IC package, and then a layer of thermal paste may be applied to provide direct interface to and contact with the pedestal without compressing the thermal pad. In the same or a different embodiment, a sandwich configuration may be used in which, for example, a layer of thermal paste is applied to each of the IC package and the pedestal, and a thermal pad is sandwiched between the two. In the same or a different environment, a different sandwich configuration may be provided in which a thermal pad is applied to each of the IC package and the pedestal of the cold plate, and a layer of thermal paste is provided between the two to help alleviate compression. In the same or a different embodiment, a thermal pad may be provided with dimensions that do not conform precisely to a top surface of the IC. As described above, the thermal pad may include electromagnetic absorption material, and thus to enhance EMI performance, an oversized thermal pad may be provided that can at least partially wrap around the IC. This can prevent leakage of electromagnetic radiation from the sides of the IC as well as from the top of the IC. A layer of thermal paste may then be provided on top of the thermal pad so that contact with the pedestal of the cold plate does not cause compression of the oversized thermal pad and possible damage to the IC or its solder points.

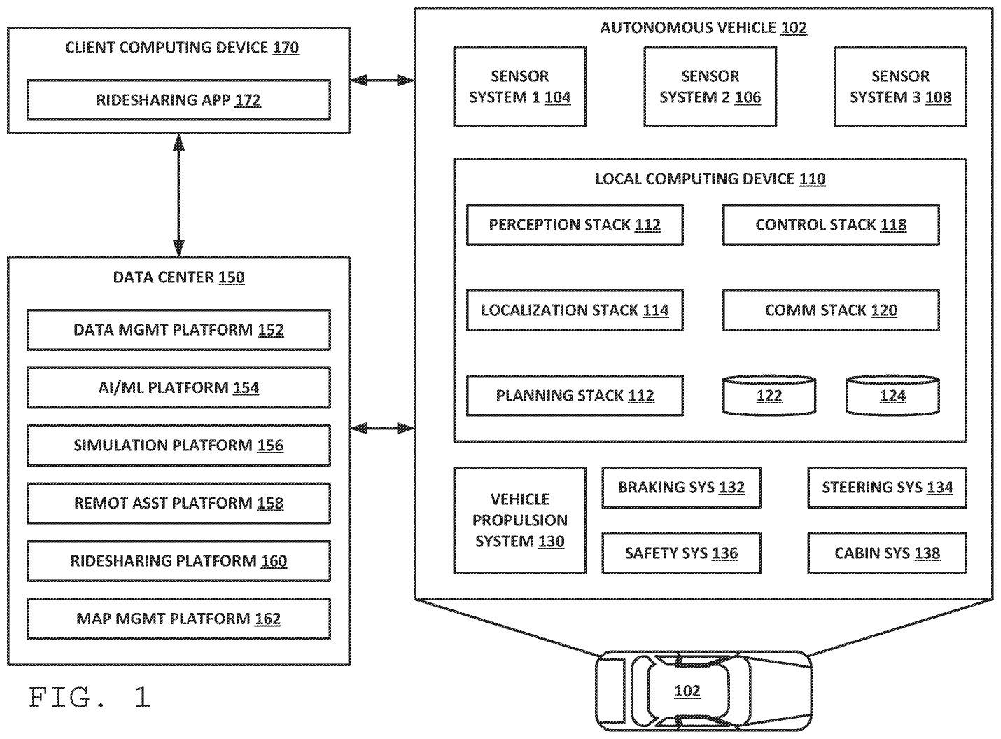

FIG. 1 illustrates an example of an AV management system 100. AV management system 100 may include active electronics that require cooling, and thus may benefit from the teachings of this specification. One of ordinary skill in the art will understand that, for the AV management system 100 and any system discussed in the present disclosure, there may be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 may communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 102 may navigate about roadways without a human driver based on sensor signals generated by multiple sensor systems 104, 106, and 108. The sensor systems 104-108 may include different types of sensors and may be arranged about the AV 102. For instance, the sensor systems 104-108 may comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 may be a camera system, the sensor system 106 may be a LIDAR system, and the sensor system 108 may be a RADAR system. Other embodiments may include any other number and type of sensors.

AV 102 may also include several mechanical systems that may be used to maneuver or operate AV 102. For instance, the mechanical systems may include vehicle propulsion system 130, braking system 132, steering system 134, safety system 136, and cabin system 138, among other systems. Vehicle propulsion system 130 may include an electric motor, an internal combustion engine, or both. The braking system 132 may include an engine brake, a wheel braking system (e.g., a disc braking system that utilizes brake pads), hydraulics, actuators, and/or any other suitable componentry configured to assist in decelerating AV 102. The steering system 134 may include suitable componentry configured to control the direction of movement of the AV 102 during navigation. Safety system 136 may include lights and signal indicators, a parking brake, airbags, and so forth. The cabin system 138 may include cabin temperature control systems, in-cabin entertainment systems, and so forth. In some embodiments, the AV 102 may not include human driver actuators (e.g., steering wheel, handbrake, foot brake pedal, foot accelerator pedal, turn signal lever, window wipers, etc.) for controlling the AV 102. Instead, the cabin system 138 may include one or more client interfaces (e.g., Graphical User Interfaces (GUIs), Voice User Interfaces (VUIs), etc.) for controlling certain aspects of the mechanical systems 130-138.

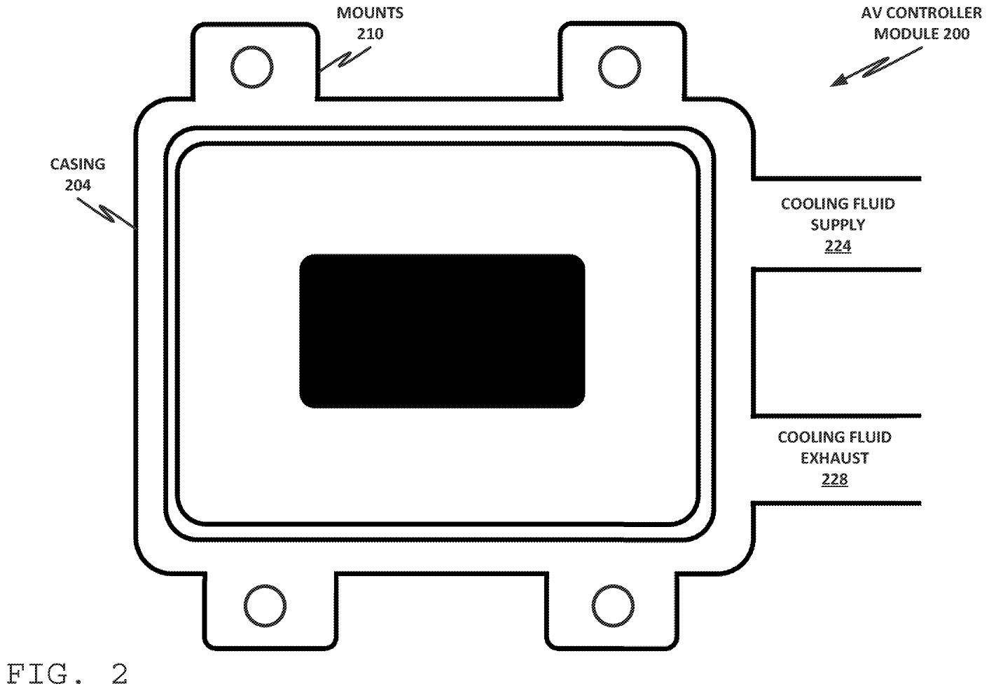

AV 102 may additionally include a local computing device 110 that is in communication with the sensor systems 104-108, the mechanical systems 130-138, the data center 150, and the client computing device 170, among other systems. The local computing device 110 may include one or more processors and memory, including instructions that may be executed by the one or more processors. The instructions may make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108 and so forth. In this example, the local computing device 110 includes a perception stack 112, a mapping and localization stack 114, a planning stack 112, a control stack 118, a communications stack 120, an High Definition (HD) geospatial database 122, and an AV operational database 124, among other stacks and systems. In some embodiments, local computing device 110 may include a controller module similar to the module illustrated in FIG. 2 below, which may be cooled by a cold plate, and which may benefit from a multilayer TIM.

Perception stack 112 may enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 122, other components of the AV, and other data sources (e.g., the data center 150, the client computing device 170, third-party data sources, etc.). The perception stack 112 may detect and classify objects and determine their current and predicted locations, speeds, directions, and the like. In addition, the perception stack 112 may determine the free space around the AV 102 (e.g., to maintain a safe distance from other objects, change lanes, park the AV, etc.). The perception stack 112 may also identify environmental uncertainties, such as where to look for moving objects, flag areas that may be obscured or blocked from view, and so forth.

Mapping and localization stack 114 may determine the AV's position and orientation (pose) using different methods from multiple systems (e.g., GPS, IMUs, cameras, LIDAR, RADAR, ultrasonic sensors, the HD geospatial database 122, etc.). For example, in some embodiments, the AV 102 may compare sensor data captured in real-time by the sensor systems 104-108 to data in the HD geospatial database 122 to determine its precise (e.g., accurate to the order of a few centimeters or less) position and orientation. The AV 102 may focus its search based on sensor data from one or more first sensor systems (e.g., GPS) by matching sensor data from one or more second sensor systems (e.g., LIDAR). If the mapping and localization information from one system is unavailable, the AV 102 may use mapping and localization information from a redundant system and/or from remote data sources.

The planning stack 116 may determine how to maneuver or operate the AV 102 safely and efficiently in its environment. For example, the planning stack 116 may receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 102 from one point to another. The planning stack 116 may determine multiple sets of one or more mechanical operations that the AV 102 may perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 116 may select from multiple backup plans to carry out. For example, while preparing to change lanes to turn right at an intersection, another vehicle may aggressively cut into the destination lane, making the lane change unsafe. The planning stack 116 could have already determined an alternative plan for such an event, and upon its occurrence, help to direct the AV 102 to go around the block instead of blocking a current lane while waiting for an opening to change lanes.

The control stack 118 may manage the operation of the vehicle propulsion system 130, the braking system 132, the steering system 134, the safety system 136, and the cabin system 138. The control stack 118 may receive sensor signals from the sensor systems 104-108 as well as communicate with other stacks or components of the local computing device 110 or a remote system (e.g., the data center 150) to effectuate operation of the AV 102. For example, the control stack 118 may implement the final path or actions from the multiple paths or actions provided by the planning stack 116. Implementation may involve turning the routes and decisions from the planning stack 116 into commands for the actuators that control the AV's steering, throttle, brake, and drive unit.

The communication stack 120 may transmit and receive signals between the various stacks and other components of the AV 102 and between the AV 102, the data center 150, the client computing device 170, and other remote systems. The communication stack 120 may enable the local computing device 110 to exchange information remotely over a network, such as through an antenna array or interface that may provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 120 may also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 122 may store HD maps and related data of the streets upon which the AV 102 travels. In some embodiments, the HD maps and related data may comprise multiple layers, such as an areas layer, a lanes and boundaries layer, an intersections layer, a traffic controls layer, and so forth. The areas layer may include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer may include geospatial information of road lanes (e.g., lane or road centerline, lane boundaries, type of lane boundaries, etc.) and related attributes (e.g., direction of travel, speed limit, lane type, etc.). The lanes and boundaries layer may also include 3D attributes related to lanes (e.g., slope, elevation, curvature, etc.). The intersections layer may include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer may include geospatial information of traffic signal lights, traffic signs, and other road objects and related attributes.

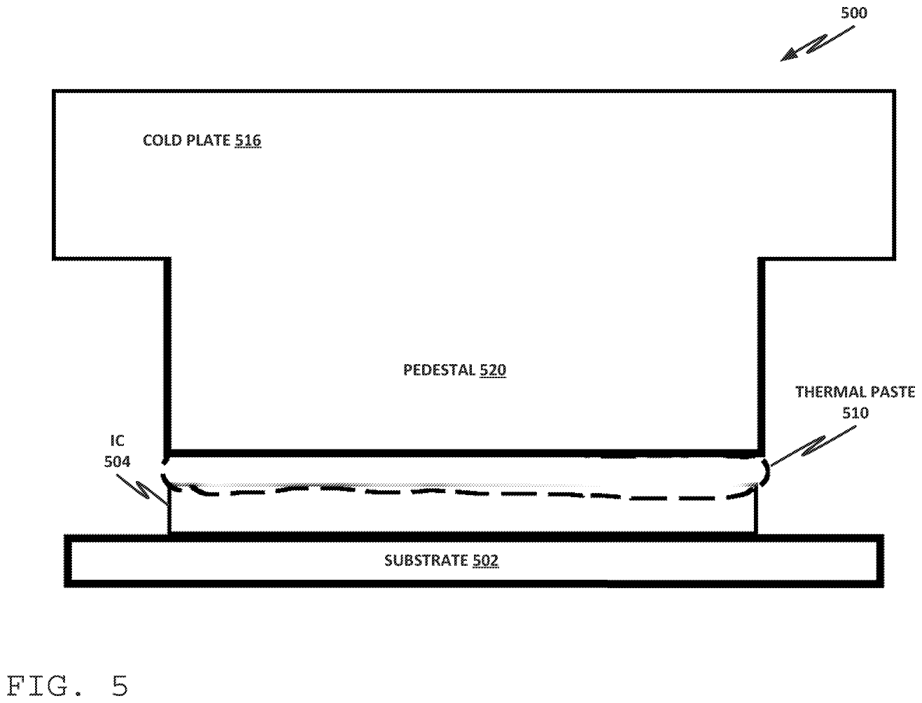

The AV operational database 124 may store raw AV data generated by the sensor systems 104-108 and other components of the AV 102 and/or data received by the AV 102 from remote systems (e.g., the data center 150, the client computing device 170, etc.). In some embodiments, the raw AV data may include HD LIDAR point cloud data, image or video data, RADAR data, GPS data, and other sensor data that the data center 150 may use for creating or updating AV geospatial data as discussed further below with respect to FIG. 5 and elsewhere in the present disclosure.

The data center 150 may be a private cloud (e.g., an enterprise network, a co-location provider network, etc.), a public cloud (e.g., an IaaS network, a PaaS network, a SaaS network, or other CSP network), a hybrid cloud, a multi-cloud, and so forth. The data center 150 may include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 may send and receive various signals to and from the AV 102 and the client computing device 170. These signals may include sensor data captured by the sensor systems 104-108, roadside assistance requests, software updates, ridesharing pick-up and drop-off instructions, and so forth. In this example, the data center 150 includes one or more of a data management platform 152, an Artificial Intelligence/Machine Learning (AI/ML) platform 154, a simulation platform 156, a remote assistance platform 158, a ridesharing platform 160, and a map management platform 162, among other systems.

Data management platform 152 may be a “big data” system capable of receiving and transmitting data at high speeds (e.g., near real-time or real-time), processing a large variety of data, and storing large volumes of data (e.g., terabytes, petabytes, or more of data). The varieties of data may include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 may access data stored by the data management platform 152 to provide their respective services.

The AI/ML platform 154 may provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists may prepare data sets from the data management platform 152; select, design, and train machine learning models; evaluate, refine, and deploy the models; maintain, monitor, and retrain the models; and so on.

The simulation platform 156 may enable testing and validation of the algorithms, machine learning models, neural networks, and other development efforts for the AV 102, the remote assistance platform 158, the ridesharing platform 160, the map management platform 162, and other platforms and systems. The simulation platform 156 may replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162; modeling the behavior of other vehicles, bicycles, pedestrians, and other dynamic elements; simulating inclement weather conditions, different traffic scenarios; and so on.

The remote assistance platform 158 may generate and transmit instructions regarding the operation of the AV 102. For example, in response to an output of the AI/ML platform 154 or other system of the data center 150, the remote assistance platform 158 may prepare instructions for one or more stacks or other components of the AV 102.

The ridesharing platform 160 may interact with a customer of a ridesharing service via a ridesharing application 172 executing on the client computing device 170. The client computing device 170 may be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general-purpose computing device for accessing the ridesharing application 172. The client computing device 170 may be a customer's mobile computing device or a computing device integrated with the AV 102 (e.g., the local computing device 110). The ridesharing platform 160 may receive requests to be picked up or dropped off from the ridesharing application 172 and dispatch the AV 102 for the trip.

Map management platform 162 may provide a set of tools for the manipulation and management of geographic and spatial (geospatial) and related attribute data. The data management platform 152 may receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data may be processed, and map management platform 162 may render base representations (e.g., tiles (2D), bounding volumes (3D), etc.) of the AV geospatial data to enable users to view, query, label, edit, and otherwise interact with the data. Map management platform 162 may manage workflows and tasks for operating on the AV geospatial data. Map management platform 162 may control access to the AV geospatial data, including granting or limiting access to the AV geospatial data based on user-based, role-based, group-based, task-based, and other attribute-based access control mechanisms. Map management platform 162 may provide version control for the AV geospatial data, such as to track specific changes that (human or machine) map editors have made to the data and to revert changes when necessary. Map management platform 162 may administer release management of the AV geospatial data, including distributing suitable iterations of the data to different users, computing devices, AVs, and other consumers of HD maps. Map management platform 162 may provide analytics regarding the AV geospatial data and related data, such as to generate insights relating to the throughput and quality of mapping tasks.

In some embodiments, the map viewing services of map management platform 162 may be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

FIG. 2 is a block diagram illustration of selected components of an AV controller module 200. AV controller module 200 is disposed within a casing 204. Casing 204 may be, for example, a metal casing, such as aluminum, stainless steel, or some other material. Casing 204 may also be a nonmetallic material, such as a polymer, carbon fiber, or other. AV controller module 200 may mount to a surface via mounts 210, which in this illustration are provided at four corners of casing 204. Other configurations may also be used.

Internal to AV controller module 200 is one or more PCBs, which are cooled by one or more cold plates. In this illustration, the cold plate is liquid cooled. For example, a cooling fluid supply 224 may be provided via a hose, hardline, or other conduit to the cold plate. Cooling fluid supply 224 may provide cool fluid into the cold plate. The cool fluid may circulate through the cold plate, wherein it consumes heat from the electronics. Fluid may then circulate out via cooling fluid exhaust 228. Cooling fluid exhaust 228 may also be a hose, port, or other conduit. After cooling fluid leaves via cooling fluid exhaust 228, the heat may be expelled, such as via evaporation or other means.

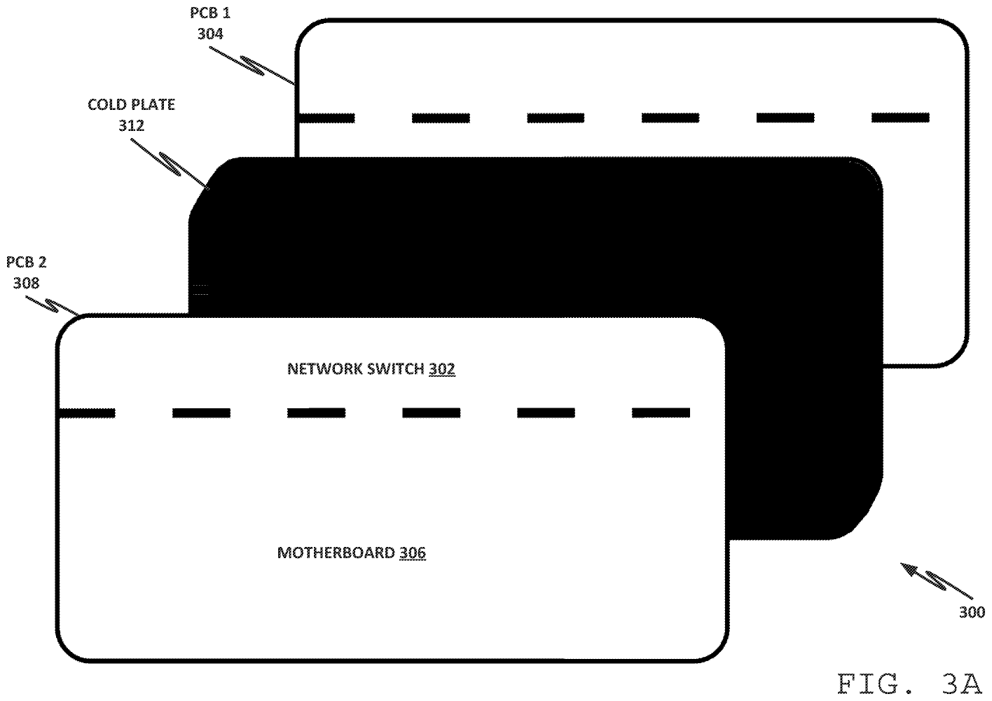

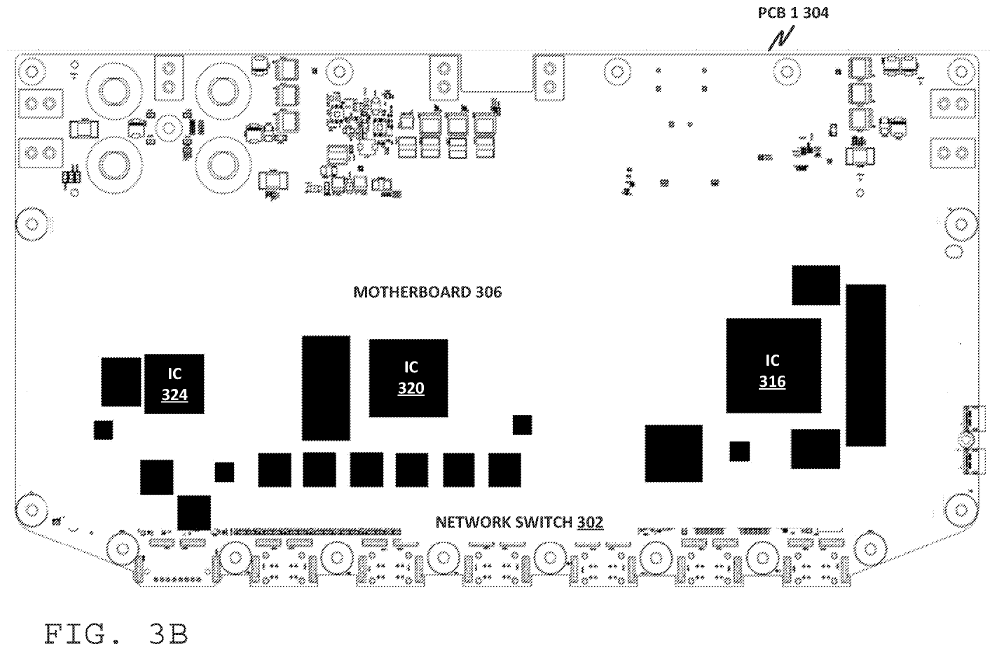

FIGS. 3A and 3B provide an illustrative arrangement of an AV controller module 300. AV controller module 300 may be the same as AV controller module 200 of FIG. 2 or a different configuration.

In this example, AV controller module 300 includes two PCBs, namely PCB 1 304 and PCB 2 308. Depending on the embodiment and the use case, these could provide different circuitry or they could provide redundant circuitry. For example, in the case of an AV, redundant circuitry may be an important design consideration to ensure that, if one controller circuit encounters a problem, the other can safely take over and continue to operate the AV. By way of illustration, in the case of an AV controller, PCB 2 308 includes an upper portion that provides a network switch 302. This provides the network connections that are necessary to interconnect AV controller 300 with the rest of the vehicle, including various sensors, communications systems, and others. PCB 2 308 also includes a motherboard 306, which may provide the active control logic for the PCB. As discussed above, PCB 2 308 may be essentially duplicated in PCB 1 304 so that redundant control is provided.

Alternatively, PCB 2 308 may provide different circuitry, such as support or auxiliary circuitry, or primary circuitry may be divided between the two PCBs. In yet another embodiment, switch board 302 and motherboard 306 are two separate boards, and FIG. 3b below may include only the motherboard. In yet another embodiment, one o more boards may provide a combination board with a switch board and a power distribution board (PDB). In yet another embodiment, PCB 1 304 may provide a motherboard, while PCB 2 308 may provide a combination switch board and PDB. Other configurations may also be provided.

A cold plate 312 may be disposed between PCB 1 304 and PCB 2 308. As discussed above, cold plate 312 may circulate cooling fluid in various ways and may conduct heat away from PCB 1 304 and PCB 2 308. Cold plate 312 may also include a number of pedestals that are designed to interface specifically with certain ICs on the PCBs. This may be more visible in FIG. 3B, which shows additional selected details of AV controller 300. In FIG. 3, PCB 1 304 is shown with additional illustrative detail. PCB 1 304 may include a number of analog, digital, and/or mixed signal components. PCB 1 304 includes a number of ICs, illustrated in black, which may be source of primary concern for one or both of heat and EMI. For example, IC 316, IC 320, IC 324, and other ICs illustrated here in black may provide electromagnetic noise that may interfere with wireless components if not mitigated. Thus, cold plate 312 may have pedestals that closely match the shape and location of the ICs 316, 320, 324, and others. These pedestals may be designed to come within a gap of the ICs but not necessarily to physically contact the ICs, which in, some cases, may cause damage. Instead, a TIM may be provided between the ICs and the pedestal.

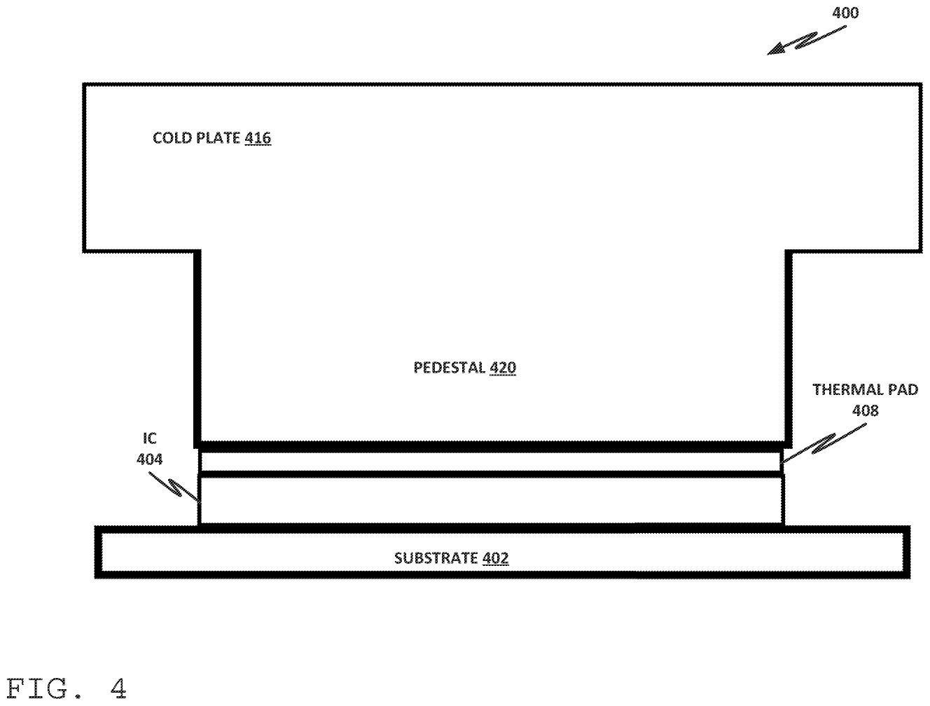

FIG. 4 is a block diagram illustration of a cooling configuration 400. IC 404 sits on a substrate 402, such as an acrylic circuit board or any other suitable substrate. IC 404 may be soldered to substrate 402. Pedestal 420 may be a protrusion from cold plate 416, which is designed to closely match the shape and location of IC 404. Alternatively, pedestal 420 may be a metal block of the appropriate size and shape, soldered to the cold plate. Pedestal 420 may be manufactured with a tolerance such that thermal pad 408 may fit closely between IC 404 and pedestal 420. Thus, thermal pad 408 may conduct heat away from IC 404 and into pedestal 420 where the liquid cooling properties of cold plate 416 can carry the heat away and thus prevent damage to IC 404.

As discussed above, in at least some examples, thermal pad 408 may require certain design trade-offs. For example, the more tightly thermal pad 408 fits between IC 404 and pedestal 420, the better heat conduction it may provide. However, if the fit is too tight, thermal pad 408 may damage IC 404 when the PCB is assembled to cold plate 416. Thermal pad 408 experimentally was provided with EMI absorption material and was found to provide good EMI protection.

For example, with a nominal gap between the pedestal and the IC of 1 mm, 1.5 mm thermal pads were found to have the following properties:

| | | (+) | (−) | | |
|---|---|---|---|---|---|
| | Nominal | tolerance | tolerance | Cp | stdev |
| Pedestal Height | N/A | 0.15 | 0.15 | 1 | 0.05 |
| Chip Height | N/A | 0.2 | 0.2 | 1 | 0.0666 |
| TIM Space After | 1 | 0.35 | 0.35 | | |
| Assembly | | | | | |
| 3σ TIM Space | 1 | 0.25 | 0.25 | 1 | 0.08333 |
| After Assembly | | | | | |
| Thermal Pad | 1.5 | 0.15 | 0.15 | | |
| Original Thickness | | | | | |

| | Nominal | MAX | MIN |
|---|---|---|---|
| Thermal Pad Compression | 33.33% | 60.61% | 0.00% |
| Thermal Pad Pressure | ~43 psi | ~85 psi | 0 psi |
| 3σ Thermal Pad Compression | 33.33% | 54.55% | 7.41% |
| 3σ Thermal Pad Pressure | ~43 psi | ~72 psi | ~11 psi |

Although these pads provided adequate thermal conduction and EMI protection, they exerted unacceptably high pressure on the ICs they cooled. Furthermore, when the IC heats, the thermal pads expand, which causes further compression of the material. This may increase the danger of damage to the chip because of the increased pressure. When the IC cools again, the compressed material may not rebound to its original shape. Thus, when the IC cools, an air gap may form between the thermal pads and the IC or pedestal.

Thermal pads of 1.0 mm were also calculated and tested. They provided no thermal conduction when not completely filling the gap between the IC and the pedestal, and provided less EMI protection in general. Furthermore, although less extreme, at the worst case scenario of tolerance stack-up, they also provided unacceptably high compression on the ICs for the particular use case.

Results for 1.0 mm were as follows:

| | | (+) | (−) | | |
|---|---|---|---|---|---|
| | Nominal | tolerance | tolerance | Cp | stdev |
| Pedestal Height | N/A | 0.15 | 0.15 | 1 | 0.05 |
| Chip Height | N/A | 0.2 | 0.2 | 1 | 0.0666 |
| TIM Space After | 1 | 0.35 | 0.35 | | |
| Assembly | | | | | |
| 3σ TIM Space | 1 | 0.25 | 0.25 | 1 | 0.08333 |
| After Assembly | | | | | |
| Thermal Pad | 1 | 0.1 | 0.1 | | |
| Original Thickness | | | | | |

| | Nominal | MAX | MIN |
|---|---|---|---|
| Thermal Pad Compression | 0% | 40.9% | 0% |
| Thermal Pad Pressure | 0 psi | ~52 psi | 0 psi |
| 3σ Thermal Pad Compression | 0% | 31.82% | 0% |
| 3σ Thermal Pad Pressure | 0 psi | ~42 psi | 0 psi |

FIG. 5 illustrates an alternative configuration 500. Thermal configuration 500 forgoes the thermal pad and instead uses a thermal paste 510 between pedestal 520 and IC 504. As before, IC 504 is soldered to a substrate 502, such as an acrylic circuit board. Pedestal 520 is part of cold plate 516 and provides heat conduction away from IC 504. Experimentally, this configuration was found to have superior thermal conduction properties as compared to configuration 400 of FIG. 4. Furthermore, the use of thermal paste 510 provides little or no risk of damage from compression force on IC 504. Furthermore, thermal paste 510 may not compress (and fail to rebound) like thermal pad 408 of FIG. 4, thus reducing the risk of gaps forming. Thus, thermal paste 510 may provide good mechanical and thermal properties but may have little or no EMI protection capability.

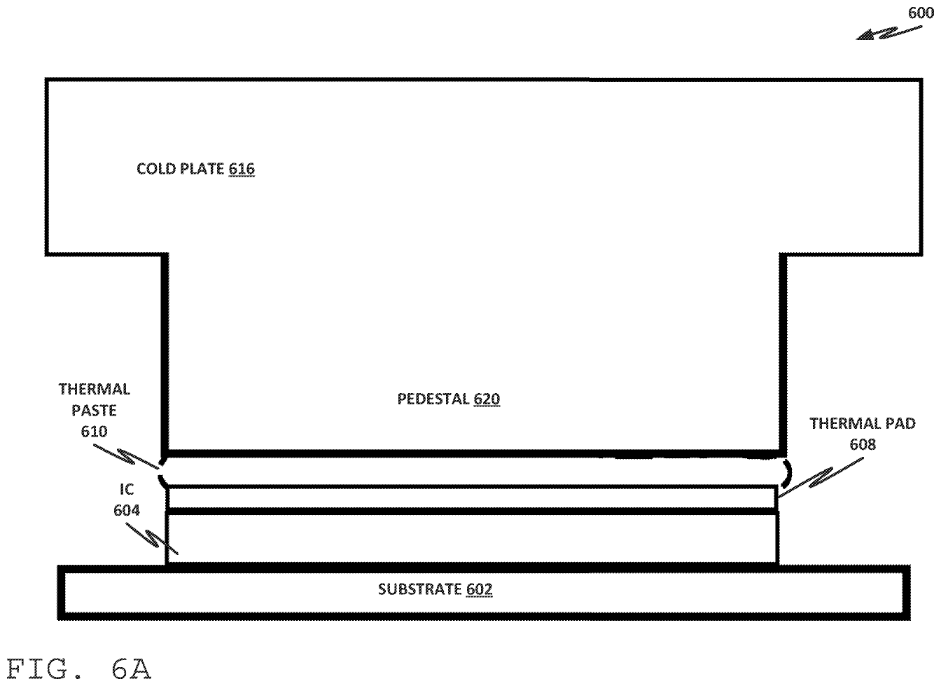

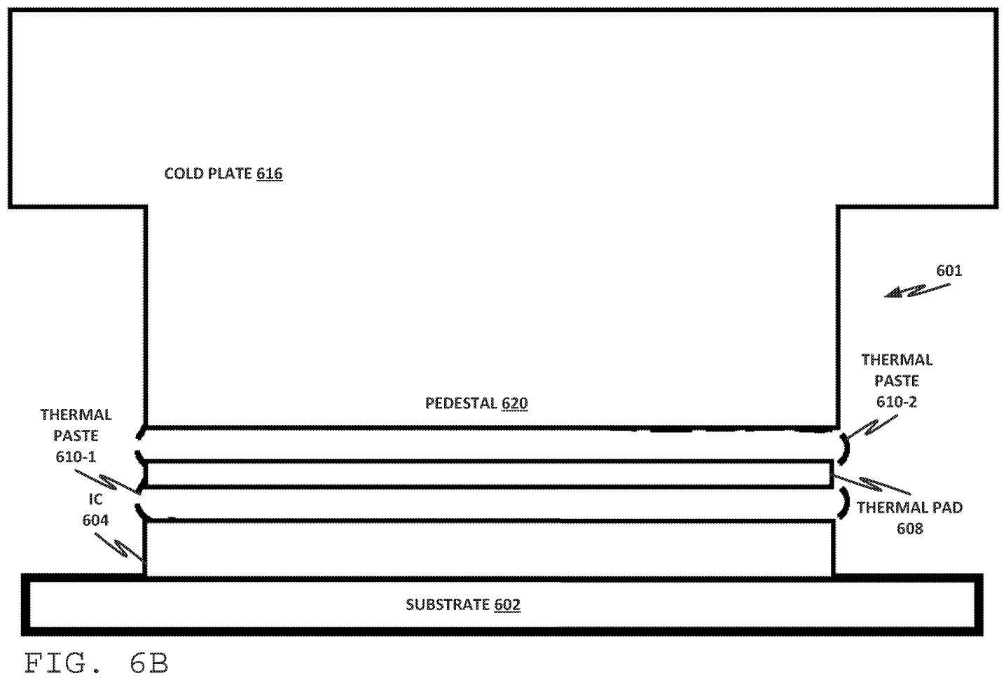

FIG. 6A illustrates a thermal configuration 600 that provides good thermal conductivity, good mechanical properties, and good EMI absorption. In this example, IC 604 is mounted to substrate 602, such as a PCB, and may be soldered. Pedestal 620 is part of cold plate 616 and conducts heat away from IC 604. A nominal gap exists between pedestal 620 and IC 604. In this case, thermal pad 608 may be designed to deliberately be smaller than the nominal gap between pedestal 620 and IC 604. Thus, thermal pad 608 does not provide direct contact to pedestal 620. Rather, direct contact is provided via thermal paste 610, which is a flowable material with little to no danger of compression damage to IC 604. Thus, thermal pad 608 provides heat conduction as well as EMI protection. Thermal paste 610 may provide an interface between thermal pad 608 and pedestal 620 without providing too much compression. Experimentally, this configuration was found to have heat conduction properties very similar to using a thermal paste alone but also had better EMI protection properties. This may avoid over-compression of components while also providing EMI protection.

In an illustrative embodiment, a 1-millimeter thermal pad 608 may be placed onto the surface of IC 604. In the same or a different embodiment, a precompression force may be applied by a specially-designed tool to compress the thermal pad onto the chip surface. This precompression may reach a target compression value for thermal pad 608 while not compressing too much, to avoid damage of IC 604 or its solder joints. The flowable TIM, such as a thermal paste 610, may then be dispensed onto cold plate pedestal 620 and may be used with less volume than would be used in a pure thermal paste embodiment. This is to account for the smaller gap because part of the gap is occupied by thermal pad 608. The PCB may then be assembled onto cold plate 616.

This configuration was found to have EMI absorption properties similar to the use of a pure thermal pad and heat conduction properties similar to the use of a pure thermal paste.

In a further test embodiment, the nominal gap between IC 604 and pedestal 620 was increased to 1.5 mm. With only a 1.0 mm thermal pad, this would incur a substantial thermal penalty because of the 0.5 mm (nominal) air gap. Results for this configuration are shown below.

| | Nominal | (+) tolerance | (−) tolerance | Cp | stdev |
|---|---|---|---|---|---|
| Pedestal Height | N/A | 0.15 | 0.15 | 1 | 0.05 |
| Chip Height | N/A | 0.2 | 0.2 | 1 | 0.0666 |
| TIM Space After | 1.5 | 0.35 | 0.35 | | |
| Assembly | | | | | |
| 3σ TIM Space | 1.5 | 0.25 | 0.25 | 1 | 0.08333 |
| After Assembly | | | | | |
| Thermal Pad | 1 | 0.1 | 0.1 | | |
| Original | | | | | |
| Thickness | | | | | |

| | Nominal | MAX | MIN |
|---|---|---|---|
| Thermal Pad | 0% | 0% | 0% |
| Compression | | | |
| Thermal Pad | 0 psi | 0 psi | 0 psi |
| Pressure | | | |
| 3σ Thermal Pad | 0% | 0% | 0% |
| Compression | | | |
| 3σ Thermal Pad | 0 psi | 0 psi | 0 psi |
| Pressure | | | |

However, when this gap is filled with thermal paste 610, the results provided much lower mechanical compression, with similar or nearly identical thermal performance (as compared to a 1.0 mm nominal gap with a 1.0 mm thermal pad). Increasing the nominal gap from 1.0 mm to 1.5 mm may prevent over-compression, and the user of a multilayer TIM can provide adequate thermal performance in this case. At some nominal gap size, the thermal performance may become unsuitable, even with the multilayer TIM. The selection of an appropriate nominal gap, appropriate sizes for the thermal pads, and appropriate volumes of thermal paste, are engineering considerations for particular embodiments. Because thermal paste 610 has fluid-like properties to some extent, excess thermal paste may generally spread thinner and/or run off the sides of the IC and pedestal during assembly rather than providing substantial additional mechanical compression. Except in the case of a poor quality thermal paste that tends to fall apart during vibration, this behavior is usually not problematic.

FIG. 6B illustrates an alternative embodiment, wherein thermal pad 608 is “sandwiched” between two layers of thermal paste 610-1 and 610-2. This may be accomplished, for example, by adding a layer of thermal paste 610 to each of IC 604 and pedestal 620, and then adding thermal pad 608 on top of one or the other before assembling.

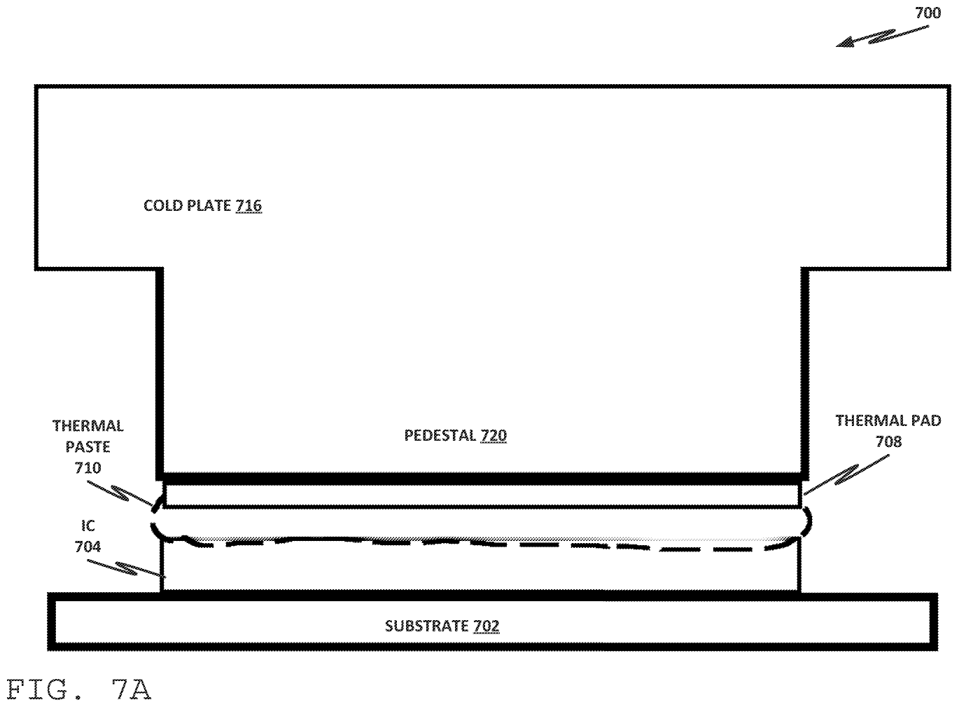

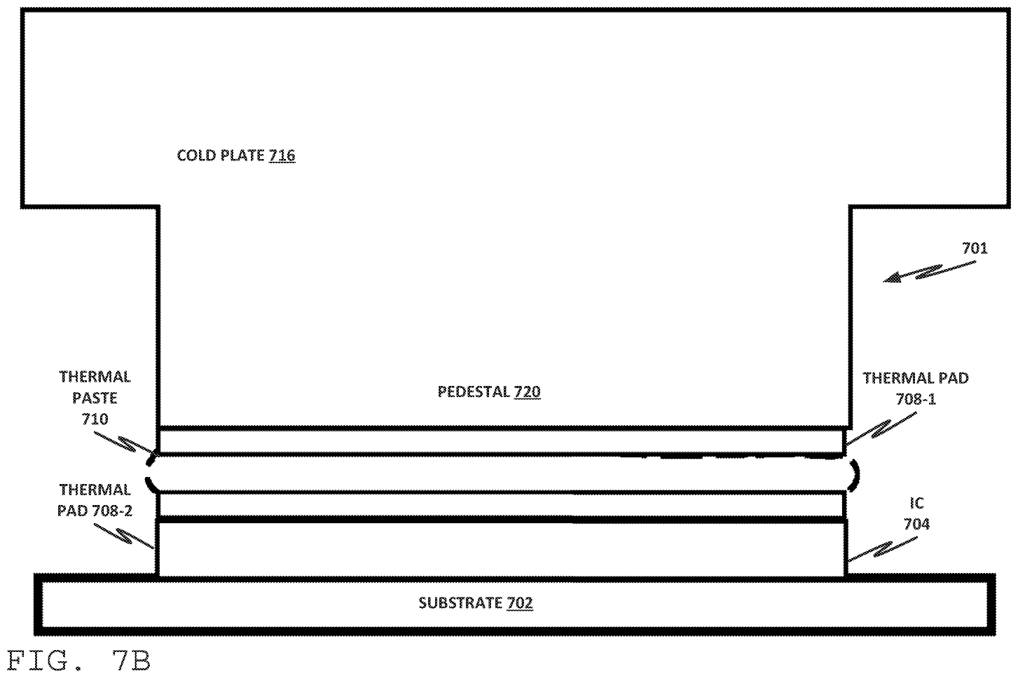

FIG. 7A provides an alternative embodiment of a thermal configuration 700. In this case, pedestal 720 is part of cold plate 716, and IC 704 is mounted to substrate 702 similar to previous figures. In this case, a thermal paste 710 is applied directly to IC 704, and a thermal pad 708 is applied directly to pedestal 720. This provides similar performance to the embodiment illustrated in FIG. 6, although in at least some cases, the embodiment provided in FIG. 6 provided slightly better EMI protection. Selection of an appropriate embodiment may depend on specific design restraints and use cases. For example, in some embodiments it may be preferable for thermal pad 708 to rest directly against pedestal 720 instead of IC 704. Cold plate 716 may be constructed of machined metal, and in at least some cases, it may be more practical to carefully machine surfaces of cold plate 716 (including pedestals 720) to better surface finish, thus having less air gaps due to surface imperfection when interfacing with TIM, as compared to IC 704, which may be a ceramic, plastic, or other package, and which may have worse surface finish.

FIG. 7B illustrates an alternative embodiment wherein thermal paste 710 is sandwiched between two thermal pads 708-1 and 708-2. This may be accomplished, for example, by adhering a thermal pad 708 to each one of IC 704 and pedestal 720, and then adding a layer of thermal paste to one or the other before assembly.

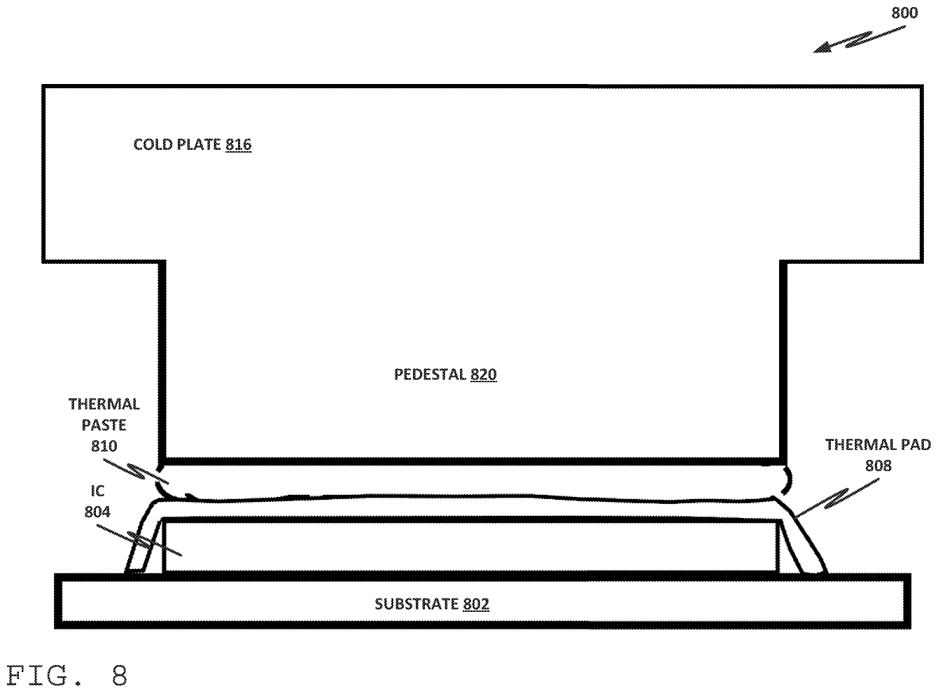

FIG. 8 is a block diagram illustration of a thermal configuration 800. Thermal configuration 800 illustrates an additional option which may be provided alongside or in addition to the previous embodiments. In this case, IC 804 is mounted to substrate 802, and pedestal 820 is part of cold plate 816. Similar to thermal configuration 500 of FIG. 5, a thermal pad 808 is mounted directly to IC 804, and a thermal paste 810 is applied to pedestal 820 before assembly. Thermal configuration 800 is different in that thermal pad 808 is an oversized thermal pad, which may be cut to dimensions such that the sides of thermal pad 808 hang over the side of IC 804. Thermal pad 808 may have dimensions such that the overhang reaches fully to substrate 802, or alternatively, that it reaches partway to substrate 802. This configuration may provide additional EMI protection because not only is the top of IC 804 shielded but also the sides are shielded.

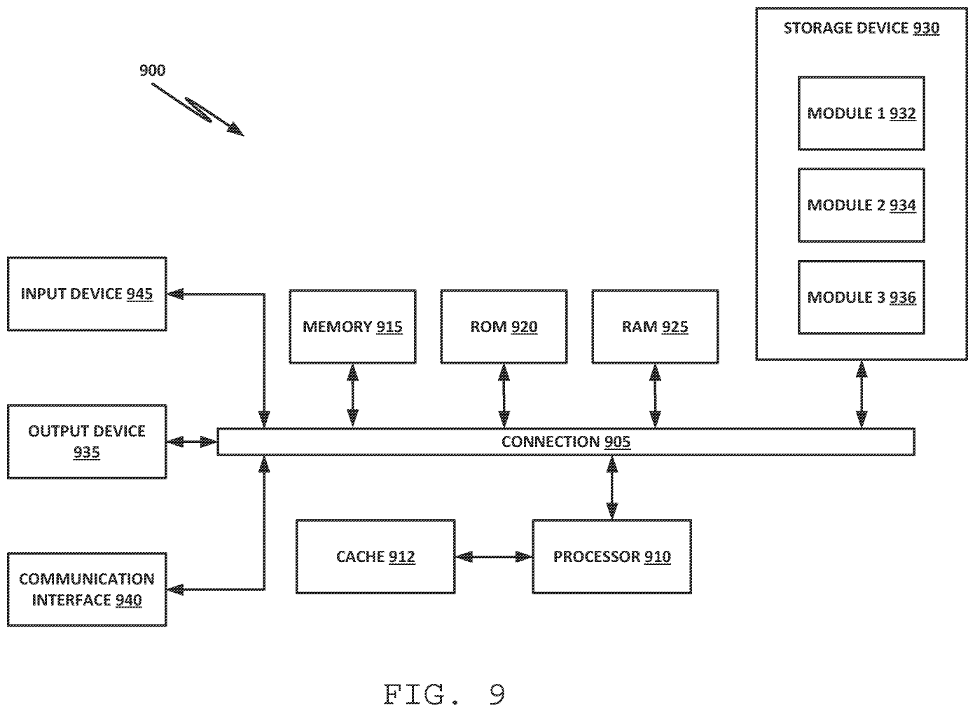

FIG. 9 illustrates an example processor-based system with which some aspects of the subject technology may be implemented. Processor-based system 900 may generate heat and may require cooling. Thus the system may benefit from the teachings of this specification. For example, processor-based system 900 may be any computing device making up, or any component thereof in which the components of the system are in communication with each other using connection 905. Connection 905 may be a physical connection via a bus, or a direct connection into processor 910, such as in a chipset architecture. Connection 905 may also be a virtual connection, networked connection, or logical connection.

In some embodiments, computing system 900 is a distributed system in which the functions described in this disclosure may be distributed within a datacenter, multiple data centers, a peer network, etc. In some embodiments, one or more of the described system components represents many such components each performing some or all of the function for which the component is described. In some embodiments, the components may be physical or virtual devices.

Example system 900 includes at least one processing unit (Central Processing Unit (CPU) or processor) 910 and connection 905 that couples various system components including system memory 915, such as Read-Only Memory (ROM) 920 and Random-Access Memory (RAM) 925 to processor 910. Computing system 900 may include a cache of high-speed memory 912 connected directly with, in close proximity to, or integrated as part of processor 910.

Processor 910 may include any general-purpose processor and a hardware service or software service, such as services 932, 934, and 936 stored in storage device 930, configured to control processor 910 as well as a special-purpose processor where software instructions are incorporated into the actual processor design. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech, a touch-sensitive screen for gesture or graphical input, keyboard, mouse, motion input, speech, etc. Computing system 900 may also include output device 935, which may be one or more of a number of output mechanisms known to those of skill in the art. In some instances, multimodal systems may enable a user to provide multiple types of input/output to communicate with computing system 900. Computing system 900 may include communications interface 940, which may generally govern and manage the user input and system output. The communication interface may perform or facilitate receipt and/or transmission wired or wireless communications via wired and/or wireless transceivers, including those making use of an audio jack/plug, a microphone jack/plug, a USB port/plug, an Apple® Lightning® port/plug, an Ethernet port/plug, a fiber optic port/plug, a proprietary wired port/plug, a Bluetooth® wireless signal transfer, a Bluetooth® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, WLAN signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 940 may also include one or more GNSS receivers or transceivers that are used to determine a location of the computing system 900 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer-readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid state memory, a Compact Disc (CD) ROM optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another IC chip/card, RAM, Atatic RAM (SRAM), Dynamic RAM (DRAM), ROM, Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 930 may include software services, servers, services, etc., that when the code that defines such software is executed by the processor 910, it causes the system 900 to perform a function. In some embodiments, a hardware service that performs a particular function may include the software component stored in a computer-readable medium in connection with the necessary hardware components, such as processor 910, connection 905, output device 935, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices may be any available device that may be accessed by a general-purpose or special-purpose computer, including the functional design of any special-purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### Selected Examples

Example 1 includes a computing apparatus, comprising: a packaged circuit comprising an exterior surface; a heat sink comprising a pedestal disposed to nearly contact the packaged circuit with a nominal clearance when the packaged circuit is assembled to the heat sink; and a first TIM and a second TIM disposed in layers between the packaged circuit and the pedestal, wherein the first TIM is non-flowable when compressed during the assembly process, and the second TIM is flowable when compressed.

Example 2 includes the computing apparatus of example 1, wherein the nominal clearance is between 1.0 and 1.5 millimeters.

Example 3 includes the computing apparatus of example 1, wherein the nominal clearance is 1.0 millimeters.

Example 4 includes the computing apparatus of example 1, wherein the nominal clearance is 1.5 millimeters.

Example 5 includes the computing apparatus of example 1, wherein the heat sink is a cold plate.

Example 6 includes the computing apparatus of example 5, wherein the cold plate is liquid cooled.

Example 7 includes the computing apparatus of example 6, wherein the cold plate comprises an evaporative cooler.

Example 8 includes the computing apparatus of example 1, wherein the first TIM further comprises a thermal pad which has electromagnetic interference (EMI) absorbing capability.

Example 9 includes the computing apparatus of example 1, wherein the second TIM comprises a thermal paste.

Example 10 includes the computing apparatus of example 9, wherein the thermal paste has an assembled thickness of between 0.1 and 0.5 millimeter.

Example 11 includes the computing apparatus of example 9, wherein the thermal paste contacts the exterior surface of the packaged circuit, and the first TIM contacts the pedestal.

Example 12 includes the computing apparatus of example 11, wherein a surface of the pedestal that contacts the first TIM is machined to within a profile tolerance of 0.3 mm.

Example 13 includes the computing apparatus of example 9, wherein the thermal paste contacts the pedestal.

Example 14 includes the computing apparatus of example 1, further comprising a second layer of the first TIM, wherein the second TIM is disposed between the two layers of the first TIM.

Example 15 includes the computing apparatus of example 1, further comprising a second layer of the second TIM, wherein the first TIM is disposed between the two layers of the second TIM.

Example 16 includes the computing apparatus of example 1, wherein the first TIM is a thermal pad.

Example 17 includes the computing apparatus of example 16, wherein the thermal pad has a nominal thickness of 1 millimeter.

Example 18 includes the computing apparatus of example 16, wherein the thermal pad has a nominal thickness of 0.75 millimeter.

Example 19 includes the computing apparatus of example 16, wherein the thermal pad has a nominal thickness of 1.5 millimeters.

Example 20 includes the computing apparatus of example 1, wherein the first TIM has a foam or foam rubber-like texture.

Example 21 includes the computing apparatus of example 1, wherein the first TIM has a surface area larger than the exterior surface of the packaged circuit.

Example 22 includes the computing apparatus of example 21, wherein the first TIM has sufficient excess dimensions to cover each side of the packaged circuit down to a substrate on which the packaged circuit rests.

Example 23 includes the computing apparatus of any of examples 1-22, wherein the computing apparatus is an embedded controller.

Example 24 includes the computing apparatus of example 23, wherein the embedded controller is a vehicle controller.

Example 25 includes the computing apparatus of example 23, wherein the embedded controller is an AV controller.

Example 26 includes the computing apparatus of example 23, wherein the embedded controller comprises first and second printed circuit boards disposed on opposite sides of the heat sink.

Example 27 includes an electronic assembly, comprising: a PCB; an IC soldered to the PCB; a cold plate comprising a pedestal that protrudes from the cold plate with a surface area that substantially matches the IC, and to sit near the IC within a nominal gap; and a multilayer TIM disposed between the IC and the cold plate, comprising a first TIM layer comprising a thermally conductive pad, and a second TIM layer comprising a thermally conductive flowable material.

Example 28 includes the electronic assembly of example 27, wherein the nominal gap is between 1.0 and 1.5 millimeters.

Example 29 includes the electronic assembly of example 27, wherein the nominal gap is 1.0 millimeters.

Example 30 includes the electronic assembly of example 27, wherein the nominal gap is 1.5 millimeters.

Example 31 includes the electronic assembly of example 27, wherein the cold plate is liquid cooled.

Example 32 includes the electronic assembly of example 31, wherein the cold plate comprises an evaporative cooler.

Example 33 includes the electronic assembly of example 27, wherein the thermally conductive pad further has electromagnetic interference (EMI) absorbing means or capability.

Example 34 includes the electronic assembly of example 27, wherein the thermally conductive flowable material is a thermal paste.

Example 35 includes the electronic assembly of example 34, wherein the thermal paste has an assembled thickness of between 0.1 and 0.5 millimeter.

Example 36 includes the electronic assembly of example 34, wherein the thermal paste contacts a top surface of the IC and the thermally conductive pad contacts a surface of the pedestal.

Example 37 includes the electronic assembly of example 36, wherein the surface of the pedestal that contacts the thermally conductive pad is machined to within a profile tolerance of 0.3 mm.

Example 38 includes the electronic assembly of example 27, wherein the thermally conductive flowable material contacts the cold plate pedestal.

Example 39 includes the electronic assembly of example 27, wherein the thermally conductive pad is a first thermally conductive pad, and further comprising a second thermally conductive pad, wherein the thermally conductive flowable material is disposed between the first thermally conductive pad and second thermally conductive pad.

Example 40 includes the electronic assembly of example 27, further comprising a second layer of thermal paste, wherein the thermally conductive pad is placed between the two layers of thermal paste.

Example 41 includes the electronic assembly of example 27, wherein the thermally conductive pad has a nominal thickness of 1 millimeter.

Example 42 includes the electronic assembly of example 27, wherein the thermally conductive pad has a nominal thickness of 0.75 millimeter.

Example 43 includes the electronic assembly of example 27, wherein the thermally conductive pad has a nominal thickness of 1.5 millimeters.

Example 44 includes the electronic assembly of example 27, wherein the thermally conductive pad has a surface area larger than a top surface of the IC.

Example 45 includes the electronic assembly of example 44, wherein the thermally conductive pad covers the IC down to the PCB.

Example 46 includes the embedded controller of example 47, wherein the thermally conductive pad has a foam or foam rubber-like texture.

Example 47 includes an embedded controller comprising the electronic assembly of any of examples 27-46.

Example 48 includes the embedded controller of example 47, wherein the embedded controller is a vehicle controller.

Example 49 includes the embedded controller of example 47, wherein the embedded controller is an AV controller.

Example 50 includes the embedded controller of example 47, wherein the embedded controller comprises first and second printed circuit boards disposed on opposite sides of the cold plate.

Example 51 includes a method of manufacturing an electronic circuit assembly, comprising: soldering an IC to a PCB; affixing a multilayer TIM to a top surface of the IC, wherein the TIM comprises a thermal pad and a thermal paste; and assembling the PCB to a cold plate, wherein the cold plate comprises a pedestal to mate with the multilayer TIM.

Example 52 includes the method of example 51, further comprising leaving a nominal gap between 1.0 and 1.5 millimeters from the IC to the pedestal.

Example 53 includes the method of example 52, wherein the nominal gap is 1.0 millimeters.

Example 54 includes the method of example 52, wherein the nominal gap is 1.5 millimeters.

Example 55 includes the method of example 51, wherein the cold plate is liquid cooled.

Example 56 includes the method of example 51, wherein the cold plate comprises an evaporative cooler.

Example 57 includes the method of example 51, wherein the thermal pad further has electromagnetic interference (EMI) absorbing means or capability.

Example 58 includes the method of example 51, wherein the thermal paste has an assembled thickness of between 0.1 and 0.5 millimeter.

Example 59 includes the method of example 51, further comprising applying the thermal paste to a top surface of the IC, and the thermal pad to contact a surface of the pedestal.

Example 60 includes the method of example 59, wherein the surface of the pedestal that contacts the thermal pad is machined to within a profile tolerance of 0.3 millimeters

Example 61 includes the method of example 51, further comprising applying the thermal paste to the cold plate pedestal.

Example 62 includes the method of example 51, further comprising sandwiching the thermal paste between two thermal pads.

Example 63 includes the method of example 51, further comprising sandwiching the thermal pad between two layers of thermal paste.

Example 64 includes the method of example 51, wherein the thermal pad has a nominal thickness of 1 millimeter.

Example 65 includes the method of example 51, wherein the thermal pad has a nominal thickness of 0.75 millimeter.

Example 66 includes the method of example 51, wherein the thermal pad has a nominal thickness of 1.5 millimeters.

Example 67 includes the method of example 51, further comprising pre-compressing the thermal pad.

Example 68 includes the method of example 51, wherein the thermal pad has a surface area larger than a surface area of the IC.

Example 69 includes the method of example 68, further comprising extending the thermal pad down to the PCB.

Example 70 includes the method of example 51, wherein the thermal pad has a foam or foam rubber-like texture.

Example 71 includes an electronic assembly constructed according to the method of any of examples 51-70.

Example 72 includes an embedded controller comprising the electronic assembly of example 71.

Example 73 includes the embedded controller of example 72, wherein the embedded controller is a vehicle controller.

Example 74 includes the embedded controller of example 72, wherein the embedded controller is an AV controller.

Example 75 includes the embedded controller of example 72, wherein the embedded controller comprises first and second printed circuit boards disposed on opposite sides of the cold plate.

Example 76 includes an apparatus comprising means for performing the method of any of examples 51-70.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

What is claimed is:

1. A computing apparatus, comprising:
a packaged circuit comprising an exterior surface;
a heat sink comprising a pedestal disposed to nearly contact the packaged circuit with a nominal clearance when the packaged circuit is assembled to the heat sink; and
a first thermal interface material (TIM) and a second TIM disposed in layers between the packaged circuit and the pedestal, wherein the first TIM is non-flowable at operating temperatures of the packaged circuit, and the second TIM is flowable at the operating temperatures.

2. The computing apparatus of claim 1, wherein the nominal clearance is between 1.0 and 1.5 millimeters.

3. The computing apparatus of claim 1, wherein the nominal clearance is 1.0 millimeters.

4. The computing apparatus of claim 1, wherein the nominal clearance is 1.5 millimeters.

5. The computing apparatus of claim 1, wherein the first TIM further comprises electromagnetic interference (EMI) means.

6. The computing apparatus of claim 1, wherein the second TIM comprises a thermal paste.

7. The computing apparatus of claim 6, wherein the thermal paste contacts the exterior surface of the packaged circuit, and the first TIM contacts the pedestal.

8. The computing apparatus of claim 7, wherein a surface of the pedestal that contacts the first TIM is machined to within a tolerance of 0.3 millimeter.

9. The computing apparatus of claim 6, wherein the thermal paste contacts the pedestal.

10. The computing apparatus of claim 1, wherein the first TIM is a thermal pad.

11. The computing apparatus of claim 10, wherein the thermal pad has a nominal thickness of between 0.75 and 1.5 millimeters.

12. The computing apparatus of claim 1, wherein the computing apparatus is a vehicle controller.

13. An electronic assembly, comprising:
a printed circuit board (PCB);
an integrated circuit (IC) soldered to the PCB;
a cold plate comprising a pedestal that protrudes from the cold plate with a surface area that substantially matches the IC, and to sit near the IC within a nominal gap; and
a multilayer thermal interface material (TIM) disposed between the IC and the cold plate, comprising a first TIM layer comprising a thermally conductive pad, and a second TIM layer comprising a thermally conductive flowable material.

14. The electronic assembly of claim 13, wherein the cold plate is liquid cooled.

15. The electronic assembly of claim 14, wherein the cold plate comprises an evaporative cooler.

16. The electronic assembly of claim 13, wherein the thermally conductive pad wraps around the IC.

17. A method of manufacturing an electronic circuit assembly, comprising:
soldering an integrated circuit (IC) to a printed circuit board (PCB);
affixing a multilayer thermal interface material (TIM) to a top surface of the IC, wherein the TIM comprises a thermal pad and a thermal paste; and
assembling the PCB to a cold plate, wherein the cold plate comprises a pedestal to mate with the multilayer TIM.

18. The method of claim 17, further comprising sandwiching the thermal paste between two thermal pads.

19. The method of claim 17, further comprising sandwiching the thermal pad between two layers of thermal paste.

20. The method of claim 17, further comprising pre-compressing the thermal pad.
